(19) United States
(12) Patent Application Publication
(10) Pub. No.: US 2005/0146385 A1
(43) Pub. Date: Jul. 7, 2005

(54) Power-on reset circuit

(76) Inventors: Luke A. Johnson, Tempe, AZ (US); Robert W. Santucci, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/748,503

(22) Filed: Dec. 29, 2003

(51) Int. Cl. H03B 1/00

(52) U.S. Cl. 331/74

(57) ABSTRACT

In some embodiments an apparatus includes an oscillator and a delay unit to provide a delay in response to an output of the oscillator. The delay unit is to provide an output to be used as a power-on reset signal. Other embodiments are described and claimed.

### TECHNICAL FIELD

The inventions generally relate to a power-on reset circuit.

### BACKGROUND

Many designs for electronic devices (electronic parts) need a power-on reset circuit to bring the device to a known state when power is applied. In many cases, an externally generated reset is not available, or the cost of an extra reset pin is prohibitive. Therefore, for a variety of reasons, it is advantageous to have an electronic device that is able to generate its own reset signal upon application of power. This seems like a simple task, but providing such a reset signal gets complex, particularly where there is no specification (or an inadequate specification) on the application of power.

If power is applied quickly enough, a power-on reset circuit can be easy to design. For example, it may be as simple as delaying a signal and generating a pulse that turns on with power and turns off with the delayed signal. However, such an arrangement does not work very well when power is applied slowly. When power is applied slowly one might think of an arrangement where the voltage level is detected and a reset is applied until the voltage achieves some predetermined value. This is difficult to implement, however. For example, since no band gaps will be operational while power is ramping, it is hard to determine what to use as a reliable reference. Further, there are extreme consequences to malfunction (for example, the entire device will not function properly if the reset is stuck on and permanently asserted or stuck off and never asserted). This implementation can also require trimming (test, measure, and adjust), which is too costly.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 is a circuit representation according to some embodiments of the inventions.

FIG. 2 is a timing diagram representation according to some embodiments of the inventions.

FIG. 3 is a circuit representation according to some embodiments of the inventions.

FIG. 4 is a block diagram representation according to some embodiments of the inventions.

FIG. 5 is a block diagram representation according to some embodiments of the inventions.

### DETAILED DESCRIPTION

Some embodiments of the inventions relate to a power-on reset circuit.

In some embodiments an apparatus includes an oscillator and a delay unit to provide a delay in response to an output of the oscillator. The delay unit is to provide an output to be used as a power-on reset signal.

In some embodiments a system includes an electronic device. The electronic device includes a power-on reset circuit that includes an oscillator and a delay unit to provide a delay in response to an output of the oscillator. The delay unit is to provide an output to be used as a power-on reset signal.

In some embodiments oscillating is performed. An output of the oscillating is delayed to provide a power-on reset signal.

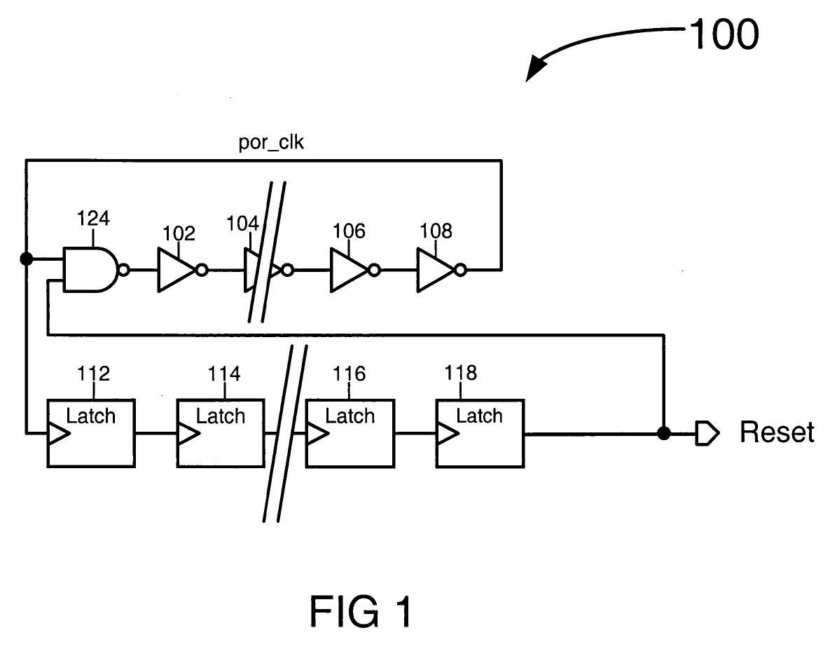

FIG. 1 illustrates a power-on reset circuit 100 according to some embodiments. Circuit 100 includes an oscillator and a delay unit (in FIG. 1, the delay unit is a counter). In some embodiments any delay unit may be used instead of a counter. In some embodiments the delay unit may be any logic that creates a delay (for example clocked digital logic). In some embodiments the delay unit may be any logic that creates a delay in response to an input clock. The oscillator includes a plurality of inverters 102, 104, 106, 108, . . . Although four inverters 102, 104, 106 and 108 are illustrated in FIG. 1, any number of inverters may be used to make up the oscillator, as shown by the double lines through inverter 104. The counter includes a plurality of latches (or flip flops) 112, 114, 116 and 118. The counter can include any number of latches, as illustrated by the double lines between latch 114 and 116. The number of latches in the counter need not correspond to the number of inverters in the oscillator. Power-on reset circuit 100 also includes a NAND gate 124.

The oscillator (including inverters 102, 104, 106, 108 and NAND gate 124) is used to drive the counter (including latches 112, 114, 116, 118). In some embodiments the oscillator is a ring oscillator. In some embodiments the counter is a binary counter. The Reset signal (for example, the power-on reset signal) is asserted and held until the oscillator begins oscillating and the counter has counted the designated number of cycles (for example, for a binary counter, 2ⁿ cycles where n is the number of latches in the binary counter). In some embodiments, when the Reset signal is de-asserted, the oscillator is disabled to save power and to prevent noise during operation.

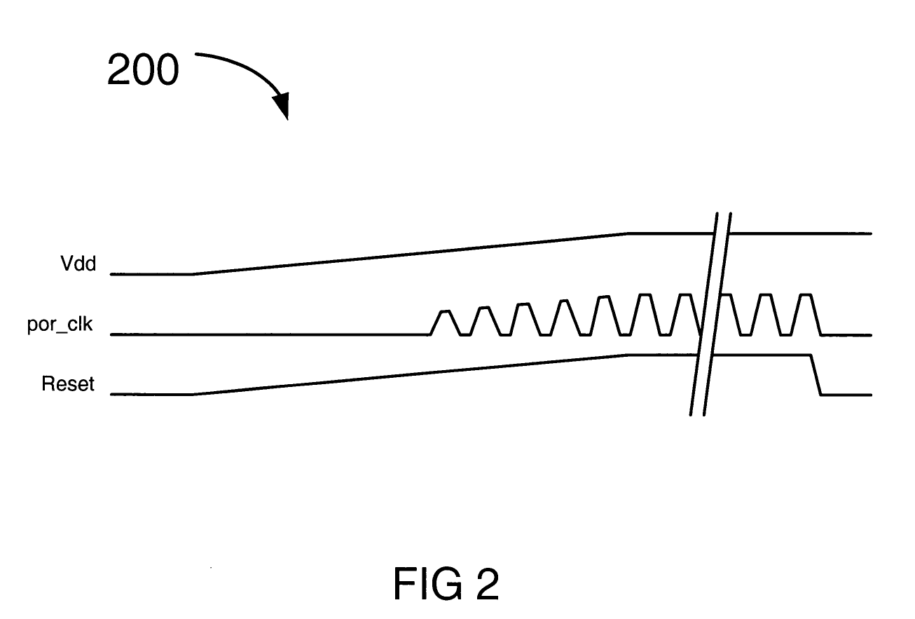

FIG. 2 illustrates signal waveforms 200 according to some embodiments. Waveforms 200 include the waveforms for the power (Vdd), power on reset clock (por_clk) and Reset (for example, power-on reset) signals of the circuit illustrated in FIG. 1, for example. The power Vdd is the power applied to the entire circuit (and, in some embodiments, the entire electronic device in which the circuit is located), including the inverters and latches of circuit 100 illustrated in FIG. 1. As illustrated in FIG. 2, the power Vdd is slowly increased (for example, upon power-on of a device in which the circuit 100 is located), the power-on reset clock signal (por_clk) begins to cycle and the Reset signal begins to be asserted. The Reset signal is asserted until a designated number of cycles are counted by the counter, and the Reset signal then is de-asserted.

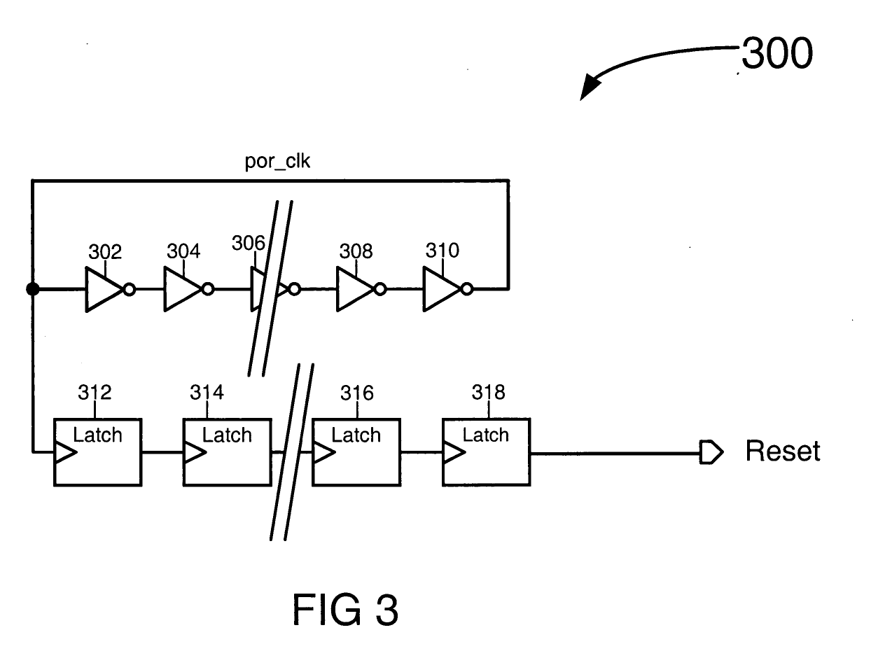

FIG. 3 illustrates a power-on reset circuit 300 according to some embodiments. Circuit 300 includes an oscillator (including inverters 302, 304, 306, . . . 308, 310) and a counter (including latches 312, 314, . . . , 316, 318). FIG. 3 does not include feedback from the Reset signal to the oscillator to enable the oscillator (via a NAND gate or some other enablement device or gate) as in the embodiment of FIG. 1, but operates in a similar manner as the circuit 100 of FIG. 1. In some embodiments the oscillator illustrated in FIG. 3 includes an odd number of inverters (for example, five interters 302, 304, 306, 308 and 310), but in some embodiments any number of inverters may be used.

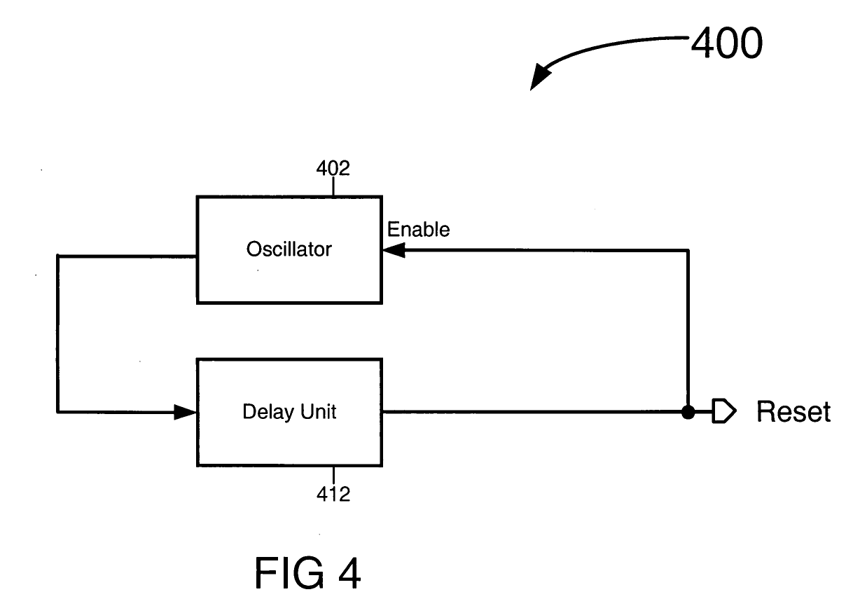

FIG. 4 illustrates a power-on reset circuit 400 according to some embodiments. Circuit 400 includes an oscillator 402 and a delay unit 412. The Reset signal (power-on reset signal) is provided to the oscillator 402 to enable the oscillator). Circuit 400 can operate in a similar manner as circuit 100 of FIG. 1 and circuit 300 of FIG. 3 according to some embodiments.

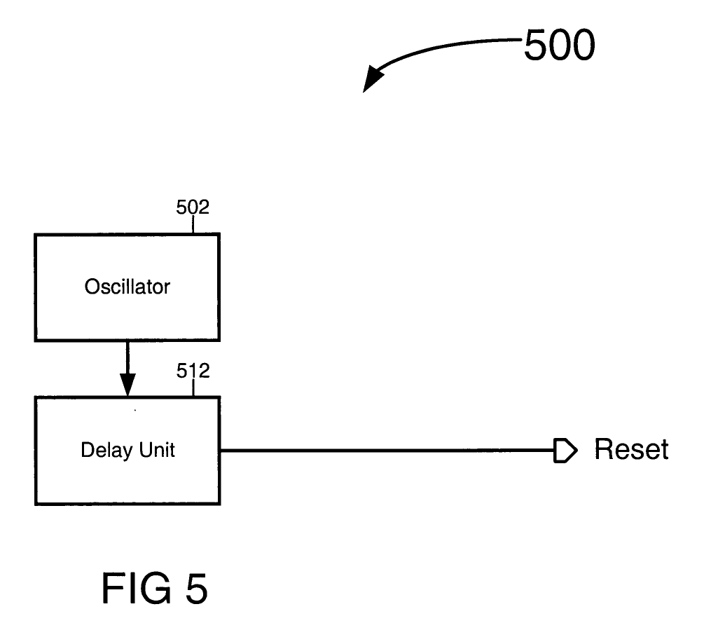

FIG. 5 illustrates a power-on reset circuit 500 according to some embodiments. Circuit 500 includes an oscillator 502 and a delay unit 512. Circuit 500 can operate in a similar manner as circuit 100 of FIG. 1, circuit 300 of FIG. 3, and circuit 400 of FIG. 5 according to some embodiments.

In some embodiments a NAND gate is used to provide the Reset signal to enable the oscillator (for example a NAND gate such as NAND gate 124 of FIG. 1). In some embodiments the NAND gate is part of the oscillator. In some embodiments the NAND gate is not part of the oscillator, but is coupled to an input of the oscillator. In some embodiments a device other than a NAND gate may be used to provide the Reset signal to enable the oscillator. For example, in some embodiments any enable device or gating device is used to provide the Reset signal to enable the oscillator. In some embodiments a NOR gate is used to provide the Reset signal to enable the oscillator.

In some embodiments a buffer is provided at an output end of the delay unit (or counter). In some embodiments the buffer is provided within the delay unit and the output of the buffer is provided as the output of the delay unit as the Reset signal. In some embodiments the buffer is provided with an input coupled to the output of the delay unit and an output provided as the Reset signal. In some embodiments the buffer is an inverter. In some embodiments (for example, those illustrated in FIG. 1) the buffer is provided with an input coupled to the output of latch 118 and an output coupled to the Reset signal (and provided to an input of NAND gate 124).

In some embodiments described and illustrated herein the oscillator is a ring oscillator. In some embodiments the oscillator is an LC oscillator. In some embodiments the oscillator is an RTC oscillator. In some embodiments the oscillator is any type of oscillator. In some embodiments the counter is a binary counter. In some embodiments the counter is a decimal counter, a shift register counter, or any other type of counter.

In some embodiments the number of inverters included in an oscillator (plus any NAND gates at the input of the oscillator) is an odd number. For example, in some embodiments with a NAND gate at an input of an oscillator, the oscillator includes four inverters (plus the NAND gate makes an odd number of five) or 2, 6, 8, etc. inverters (plus the NAND gate makes an odd number of 3, 5, 7, 9, etc.). Similarly, in some embodiments without a NAND gate at an input of the oscillator the oscillator includes five inverters (or in some embodiments 3, 5, 7, 9, etc. inverters).

In some embodiments the latches (or flip-flops, etc.) included within a counter all favor a known state (for example, “0” or “1”). This may be accomplished, for example, by ensuring that the latches used in the counter are skewed so that they will favor a particular state as power is applied. In some embodiments at least one of the latches (or flip-flops, etc.) included within a counter favor a known state. In some embodiments the most significant bit (MSB) of the counter favors a known state. In some embodiments the counter can include any number of latches (or flip-flops).

In some embodiments the oscillator and/or the counter are made of elements that have a similar power-on behavior to elements in a library that are used to make an electronic device in which the power-on circuit is included. In some embodiments the oscillator and/or the counter are made of similar elements in a library that are used to make an electronic device in which the power-on circuit is included in order to ensure a similar power-on behavior. In some embodiments the oscillator and/or the counter are made of the exact library cells that are used to make an electronic device in which the power-on circuit is included in order to ensure a similar power-on behavior. In some embodiments the oscillator and/or the counter are made up of similar elements as an electronic device in which they are included to assure that the device is sufficiently powered for the reset pulse to be effective.

In some embodiments the electronic device to which the reset signal is being provided is one or more of the following: an integrated circuit, a chip, a chip set, a digital electronic device, a micro-controller, a microprocessor, a controller, a processor, any small form factor device, a cell phone, a cell phone chip, a cell phone chip set, a next generation cell phone, a next generation cell phone chip, a next generation cell phone chip set, any electronic circuit, an embedded micro-controller, a telecommunications device, a speaker phone, and any electronic device with state retention. However, some embodiments could be used to provide the reset signal to other devices.

Although some embodiments have been described in reference to particular implementations such providing a power-on reset signal to an electronic device in which the circuit is included, other implementations are possible according to some embodiments (e.g., the circuit providing a reset signal to some other electronic device, chip, or other element, that is located, for example, on a same board as the electronic device).

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state, or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

1. An apparatus comprising:
an oscillator; and
a delay unit to provide a delay in response to an output of the oscillator, and to provide an output to be used as a power-on reset signal.

2. The apparatus according to claim 1, wherein the delay unit is logic that provides a delay in response to an input signal.

3. The apparatus according to claim 1, wherein the delay unit is a counter.

4. The apparatus according to claim 3, wherein the counter is at least one of a binary counter, a decimal counter and a shift register counter.

5. The apparatus according to claim 1, wherein the oscillator is at least one of a ring oscillator, an LC oscillator and an RTC oscillator.

6. The apparatus according to claim 1, wherein elements of the delay unit and the oscillator are chosen to have similar power-on behavior to an electronic device in which the apparatus is included.

7. The apparatus according to claim 1, wherein elements of the delay unit and the oscillator are chosen to have similar power-on behavior elements in a library used to design an electronic device in which the apparatus is included.

8. The apparatus according to claim 1, wherein elements of the delay unit and the oscillator are chosen from elements in a library used to design an electronic device in which the apparatus is included.

9. The apparatus according to claim 1, wherein the oscillator includes at least one inverter.

10. The apparatus according to claim 3, wherein the counter includes at least one latch.

11. The apparatus according to claim 10, wherein at least one latch in the counter favors a known state.

12. The apparatus according to claim 10, wherein each latch in the counter favors a known state.

13. The apparatus according to claim 10, wherein the counter includes at least two latches, and at least a most significant bit latch of the latches in the counter favors a known state.

14. The apparatus according to claim 1, wherein the power-on reset signal is provided to enable the oscillator.

15. The apparatus according to claim 14, further comprising a NAND gate having an input coupled to the power-on reset signal and an output coupled to an input of the oscillator, the NAND gate to enable the oscillator.

16. The apparatus according to claim 1, further comprising a buffer at an output of the delay unit to provide the power-on reset signal.

17. The apparatus according to claim 16, wherein the buffer is an inverter.

18. The apparatus according to claim 16, wherein the buffer is coupled to an output of the delay unit.

19. The apparatus according to claim 16, wherein the buffer is included in the delay unit.

20. The apparatus according to claim 1, wherein the apparatus is included in an electronic device and the power-on reset signal is provided within the electronic device.

21. The apparatus according to claim 20, wherein the electronic device is at least one of an integrated circuit, a chip, a chip set, a digital electronic device, a micro-controller, a microprocessor, a controller, a processor, a small form factor device, a cell phone, a cell phone chip, a cell phone chip set, a next generation cell phone, a next generation cell phone chip, a next generation cell phone chip set, an electronic circuit, an embedded micro-controller, a telecommunications device, a speaker phone, and an electronic device with state retention.

22. The apparatus according to claim 1, wherein the apparatus is included in an electronic device and the power-on reset signal is provided externally from the electronic device.

23. A system comprising:
an electronic device, including:
an oscillator; and
a delay unit to provide a delay in response to an output of the oscillator, and to provide an output to be used as a power-on reset signal.

24. The system according to claim 23, wherein the delay unit is logic that provides a delay in response to an input signal.

25. The system according to claim 23, wherein the delay unit is a counter.

26. The system according to claim 25, wherein the counter is at least one of a binary counter, a decimal counter and a shift register counter.

27. The system according to claim 23, wherein the oscillator is at least one of a ring oscillator, an LC oscillator and an RTC oscillator.

28. The system according to claim 23, wherein elements of the delay unit and the oscillator are chosen to have similar power-on behavior to the electronic device.

29. The system according to claim 23, wherein elements of the delay unit and the oscillator are chosen to have similar power-on behavior elements in a library used to design the electronic device.

30. The system according to claim 23, wherein elements of the delay unit and the oscillator are chosen from elements in a library used to design the electronic device.

31. The system according to claim 23, wherein the oscillator includes at least one inverter.

32. The system according to claim 25, wherein the counter includes at least one latch.

33. The system according to claim 32, wherein at least one latch in the counter favors a known state.

34. The system according to claim 32, wherein each latch in the counter favors a known state.

35. The system according to claim 32, wherein the counter includes at least two latches, and at least a most significant bit latch of the latches in the counter favors a known state.

36. The system according to claim 23, wherein the power-on reset signal is provided to enable the oscillator.

37. The system according to claim 36, further comprising a NAND gate having an input coupled to the power-on reset signal and an output coupled to an input of the oscillator, the NAND gate to enable the oscillator.

38. The system according to claim 23, further comprising a buffer at an output of the delay unit to provide the power-on reset signal.

39. The system according to claim 38, wherein the buffer is an inverter.

40. The apparatus according to claim 38, wherein the buffer is coupled to an output of the delay unit.

41. The apparatus according to claim 38, wherein the buffer is included in the delay unit.

42. The system according to claim 23, wherein the power-on reset signal is provided within the electronic device.

43. The system according to claim 23, wherein the electronic device is at least one of an integrated circuit, a chip, a chip set, a digital electronic device, a micro-controller, a microprocessor, a controller, a processor, a small form factor device, a cell phone, a cell phone chip, a cell phone chip set, a next generation cell phone, a next generation cell phone chip, a next generation cell phone chip set, an electronic circuit, an embedded micro-controller, a telecommunications device, a speaker phone, and an electronic device with state retention.

44. The system according to claim 23, wherein the power-on reset signal is provided externally from the electronic device.

45. A method comprising:
oscillating; and
delaying an output of the oscillating to provide a power-on reset signal.

46. The method according to claim 45, wherein the delaying of the output of the oscillating is provided by counting.

47. The method according to claim 45, further comprising providing the power-on reset signal to enable the oscillating.

48. The method according to claim 45, wherein the power-on reset signal is provided within an electronic device.

49. The method according to claim 48, wherein the electronic device is at least one of an integrated circuit, a chip, a chip set, a digital electronic device, a micro-controller, a microprocessor, a controller, a processor, a small form factor device, a cell phone, a cell phone chip, a cell phone chip set, a next generation cell phone, a next generation cell phone chip, a next generation cell phone chip set, an electronic circuit, an embedded micro-controller, a telecommunications device, a speaker phone, and an electronic device with state retention.

50. The method according to claim 45, wherein the power-on reset signal is provided externally from an electronic device.

51. The method according to claim 46, wherein the counting counts a designated number of cycles, wherein the power-on reset signal is asserted when the counting begins counting the designated number of cycles and is de-asserted when the counting finishes counting the designated number of cycles.
